(19) United States
(12) Patent Application Publication
(10) Pub. No.: US 2021/0095080 A1
(43) Pub. Date: Apr. 1, 2021

(54) THERMALLY CONDUCTIVE SHEET PRECURSOR, THERMALLY CONDUCTIVE SHEET OBTAINED FROM THE PRECURSOR, AND PRODUCTION METHOD THEREOF

(71) Applicant: 3M INNOVATIVE PROPERTIES COMPANY, St. Paul, MN (US)

(72) Inventor: Ricardo Mizoguchi Gorgoll, Sagamihara (JP)

(21) Appl. No.: 15/733,168

(22) PCT Filed: Jan. 2, 2019
(86) PCT No.: PCT/IB2019/050025

§ 371 Date: Jun. 3, 2020

(30) Foreign Application Priority Data
Jan. 9, 2018 (JP) 2018-001370

(51) Int. Cl. C08J 5/18; C08L 63/04; H01L 23/373; C08K 5/315; C08K 3/38; C08K 5/04

(52) U.S. Cl. CPC C08J 5/18; C08L 63/04; H01L 23/3737; C08K 2003/2227; C08K 3/38; C08K 5/04; C08K 2003/385; C08K 5/3155

(57) ABSTRACT

Problem: To provide a thermally conductive sheet precursor exhibiting excellent thermal conductivity and dielectric breakdown resistance, a thermally conductive sheet obtained from the precursor, and a production method thereof. Solution: The thermally conductive sheet precursor according to an embodiment of the present disclosure includes isotropic thermally conductive aggregates in which anisotropic thermally conductive primary particles are aggregated, an anisotropic thermally conductive material not constituted by the aggregates, and a binder resin; wherein upon the application of a pressure from 3 to 12 MPa to the thermally conductive sheet precursor, at least some of the isotropic thermally conductive aggregates collapse.

### TECHNICAL FIELD

The present invention relates to a thermally conductive sheet precursor exhibiting excellent thermal conductivity and dielectric breakdown resistance, a thermally conductive sheet obtained from the precursor, and a production method thereof.

### BACKGROUND ART

Heat-generating parts such as semiconductor elements may be susceptible to problems such as reduced performance and damage due to heating during use. To eliminate such problems, a sheet having thermal conductivity is used, for example, in the assembly of a power module for an electric vehicle (EV) in which a semiconductor heat spreader is mounted to a heat sink.

Patent Document 1 (JP 5036696B) describes a thermally conductive sheet produced by dispersing secondary aggregated particles, in which primary particles of scaly boron nitride are aggregated isotropically, in a thermosetting resin, wherein the secondary aggregated particles are spherical and have an average particle size of not less than 20 μm and not greater than 180 μm, a porosity of not greater than 50%, and an average pore size of not less than 0.05 μm and not greater than 3 μm; and the filling factor of the secondary aggregated particles in the thermally conductive sheet is not less than 20 vol % and not greater than 80 vol %.

### PRIOR ART DOCUMENTS

### Patent Documents

Patent Document 1: JP 5036696 B

### SUMMARY OF THE INVENTION

### Problem to be Solved by the Invention

Due to the miniaturization of power modules, increases in power, and the enhanced performance of electric vehicles, there is a demand for a new thermally conductive sheet with enhanced insulating properties and thermal conductivity. Scaly boron nitride or the like is known as a highly thermally conductive filler. Primary particles of scaly boron nitride are known to exhibit anisotropic thermal conductivity performance, wherein the primary particles exhibit high thermal conductivity in the major axis direction and exhibit low thermal conductivity in the minor axis direction (thickness direction). Therefore, in a case where scaly boron nitride is used in a thermally conductive sheet, it may be used in the form of aggregates in which primary particles of the scaly boron nitride are aggregated in random directions.

However, in the case of a thermally conductive sheet using such an aggregate, although the thermal conductivity is enhanced, low-density regions in which no scaly boron nitride or the like is present between aggregates, may be created. Such low-density regions may diminish insulation performance and may induce the malfunction of the semiconductor element or the like.

The present disclosure provides a thermally conductive sheet precursor exhibiting excellent thermal conductivity and dielectric breakdown resistance, a thermally conductive sheet obtained from the precursor, and a production method thereof.

### Means for Solving the Problem

One embodiment of the present disclosure provides a thermally conductive sheet precursor including isotropic thermally conductive aggregates in which anisotropic thermally conductive primary particles are aggregated, an anisotropic thermally conductive material not constituted by the aggregates, and a binder resin; wherein, upon the application of a pressure of from approximately 3 to approximately 12 MPa to the thermally conductive sheet precursor, at least some of the isotropic thermally conductive aggregates collapse.

Another embodiment of the present disclosure provides a thermally conductive sheet formed from the thermally conductive sheet precursor, the thermally conductive sheet having a thermal conductivity of not less than approximately 4 W/m·K and a dielectric breakdown voltage of not less than approximately 5.0 kV.

Another embodiment of the present disclosure provides a production method for a thermally conductive sheet including: preparing a mixture containing isotropic thermally conductive aggregates in which anisotropic thermally conductive primary particles are aggregated, an anisotropic thermally conductive material not constituted by the aggregates, and a binder resin; forming a thermally conductive sheet precursor using the mixture; and forming a thermally conductive sheet by applying a pressure of at least approximately 3 MPa to the thermally conductive sheet precursor.

### Effect of the Invention

The thermally conductive sheet precursor, the thermally conductive sheet obtained from the precursor, and the production method thereof according to the present disclosure can enhance the thermal conductivity and dielectric breakdown resistance of the obtained thermally conductive sheet.

The above description must not be construed to have disclosed all embodiments of the present disclosure and all advantages related to the present disclosure.

### BRIEF DESCRIPTION OF THE DRAWINGS

FIG. 1A is an SEM photograph in a case where a pressure of 0.1 MPa is applied to the thermally conductive sheet precursor according to an embodiment of the present disclosure, and FIG. 1B is an SEM photograph in a case where a pressure of 3 MPa is applied to the thermally conductive sheet precursor according to an embodiment of the present disclosure.

FIG. 2A is an SEM photograph of a region where isotropic thermally conductive aggregates are made to collapse by applying pressure to the thermally conductive sheet precursor according to an embodiment of the present disclosure, and FIG. 2B is an SEM photograph magnifying the anisotropic thermally conductive material portion of the area where the isotropic thermally conductive aggregates are made to collapse.

FIG. 3A is an optical microscope photograph taken after the thermally conductive sheet precursor according to an embodiment of the present disclosure is sintered prior to the application of pressure, and FIG. 3B is an optical microscope photograph of the thermally conductive sheet precursor according to an embodiment of the present disclosure is sintered after the application of the pressure at which the isotropic thermally conductive aggregates collapse.

FIG. 4 is a graph illustrating the relative thickness and the dielectric breakdown voltage of a thermally conductive sheet after pressure is applied to the thermally conductive sheet precursor according to an embodiment of the present disclosure.

FIG. 5 is a graph illustrating the relationship between the compounding ratios of various anisotropic thermally conductive materials and the dielectric breakdown voltage in the thermally conductive sheet according to an embodiment of the present disclosure.

FIG. 6 is a graph illustrating the relationship between the compounding ratio of an anisotropic thermally conductive material P003 and the dielectric breakdown voltage and thermal conductivity in the thermally conductive sheet according to an embodiment of the present disclosure.

FIG. 7 is a graph illustrating the relationship between the compounding ratio of an anisotropic thermally conductive material and the dielectric breakdown voltage and thermal conductivity in a thermally conductive sheet that does not contain isotropic thermally conductive aggregates and contains only secondary particles VSN1395 serving as an anisotropic thermally conductive material.

FIG. 8 is a graph illustrating the relationship between the compounding ratio of an anisotropic thermally conductive material and the dielectric breakdown voltage and thermal conductivity in a thermally conductive sheet containing isotropic thermally conductive aggregates and secondary particles VSN1395 serving as an anisotropic thermally conductive material.

FIG. 9 is a graph illustrating the relationship between thickness and the dielectric breakdown voltage in a thermally conductive sheet of a one-component system containing only isotropic thermally conductive aggregates (A100) and a thermally conductive sheet of a mixture-component system containing a mixture of isotropic thermally conductive aggregates (A100) and an anisotropic thermally conductive material (P003).

FIG. 10 is a graph regarding to the dielectric breakdown voltage and thermal conductivity in a thermally conductive sheet containing isotropic thermally conductive aggregates and an alumina powder (AA18 or AA1.5) serving as an isotropic thermally conductive material.

### DESCRIPTION OF THE PREFERRED EMBODIMENTS

The thermally conductive sheet precursor according to a first embodiment of the present disclosure contains isotropic thermally conductive aggregates in which anisotropic thermally conductive primary particles are aggregated, an anisotropic thermally conductive material not constituted by the aggregates, and a binder resin; wherein, upon the application of a pressure from approximately 3 to approximately 12 MPa to the thermally conductive sheet precursor, at least some of the isotropic thermally conductive aggregates collapse. In a case where a sheet is formed from a resin material prepared by simply blending primary particles of anisotropic thermally conductive particles of scaly boron nitride or the like, the particles tend to be arranged in one direction and tend not to express isotopic thermal conductivity. However, the thermally conductive sheet precursor of the present disclosure utilizes isotropic thermally conductive aggregates which can collapse under a prescribed pressure, and thus the anisotropic thermally conductive primary particles constituting the aggregates are easily randomized after collapse, and isotropic thermal conductivity is easily expressed in the thermally conductive sheet. An anisotropic thermally conductive material, which is not constituted by the collapsed anisotropic thermally conductive primary particles or aggregates, can at least partially fill the low-density portions of particles such as voids positioned between aggregates prior to the application of pressure, thereby reducing the infiltration of electrons after the application of pressure. Simultaneously, an anisotropic thermally conductive material, which is not constituted by the compounded aggregates, can also contribute to the enhancement of dielectric breakdown resistance as well as the enhancement of thermal conductivity.

The isotropic thermally conductive aggregates contained in the thermally conductive sheet precursor of the first embodiment may have a porosity of greater than approximately 50%. These aggregates characteristically collapse more easily under a prescribed pressure.

The thermally conductive sheet precursor of the first embodiment may contain from approximately 12.5 to approximately 57.5 vol % of isotropic thermally conductive aggregates and may contain from approximately 2.5 to approximately 37.5 vol % of an anisotropic thermally conductive material. A thermally conductive sheet precursor containing isotropic thermally conductive aggregates and an anisotropic thermally conductive material at this compounding ratio can further enhance the conductivity and dielectric breakdown resistance of the thermally conductive sheet that is ultimately obtained.

The average particle size of the isotropic thermally conductive aggregates contained in the thermally conductive sheet precursor of the first embodiment may be not less than approximately 50 μm, and the average major axis length of the anisotropic thermally conductive material may be from approximately 1 to approximately 9 μm. With such isotropic thermally conductive aggregates of this size, the anisotropic thermally conductive primary particles constituting the aggregates are easily randomized after collapse, and isotropic thermal conductivity is easily expressed in the thermally conductive sheet. Such an anisotropic thermally conductive material of this size is easily disposed between isotropic thermally conductive aggregates and exhibits excellent filling properties, and thus the anisotropic thermally conductive material can further enhance the conductivity and dielectric breakdown resistance of the thermally conductive sheet that is ultimately obtained.

The anisotropic thermally conductive material contained in the thermally conductive sheet precursor of the first embodiment may be at least one type selected from anisotropic thermally conductive primary particles and secondary particles aggregated so that anisotropic thermally conductive primary particles exhibit anisotropic thermal conductivity. Such an anisotropic thermally conductive material can further enhance the conductivity and dielectric breakdown resistance of the thermally conductive sheet that is ultimately obtained.

The primary particles of the isotropic thermally conductive aggregates contained in the thermally conductive sheet precursor of the first embodiment may be at least approximately 1.5 times greater than the primary or secondary particles of the anisotropic thermally conductive material. In a case where the isotropic thermally conductive aggregates and the anisotropic thermally conductive material are compounded with this configuration, the primary particles of the collapsed aggregates tend to be oriented randomly, and the voids or the like present between aggregates are easy to be filled with the anisotropic thermally conductive material, and thus the conductivity and dielectric breakdown resistance of the thermally conductive sheet that is ultimately obtained can be further enhanced.

The isotropic thermally conductive aggregates and the anisotropic thermally conductive material contained in the thermally conductive sheet precursor of the first embodiment may contain primary particles of boron nitride. The boron nitride exhibits excellent thermal conductivity and insulating properties, and the use of these particles can enhance both properties.

The thermally conductive sheet precursor of the first embodiment may have a thickness greater than the maximum value of the length on the side where the isotropic thermally conductive aggregates are smallest. With the thickness in such a range, problems such as the shedding of isotropic thermally conductive aggregates can be reduced.

A thermally conductive sheet of a second embodiment of the present disclosure is formed from the thermally conductive sheet precursor of the first embodiment and has a thermal conductivity not less than approximately 4 W/m·K and a dielectric breakdown voltage not less than approximately 5.0 kV.

The thermally conductive sheet of the second embodiment may include a portion in which a plurality of collapsed primary particles from the isotropic thermally conductive aggregates are locally aggregated and a portion in which a plurality of anisotropic thermally conductive materials are locally aggregated. In contrast to a thermally conductive sheet obtained from a resin material produced by simply mixing isotropic thermally conductive aggregates and an anisotropic thermally conductive material, the thermally conductive sheet obtained by applying a prescribed pressure to the thermally conductive sheet precursor of the first embodiment of the present disclosure includes the locally aggregated portions described above and can therefore enhance thermal conductivity and dielectric breakdown resistance.

A production method for a thermally conductive sheet of a third embodiment of the present disclosure includes: preparing a mixture containing isotropic thermally conductive aggregates in which anisotropic thermally conductive primary particles are aggregated, an anisotropic thermally conductive material not constituted by the aggregates, and a binder resin; forming a thermally conductive sheet precursor using the mixture; and forming a thermally conductive sheet by applying a pressure of at least approximately 3 MPa to the thermally conductive sheet precursor. A thermally conductive sheet obtained by this method can enhance conductivity and dielectric breakdown resistance.

The present disclosure will be described in further detail hereinafter with the objective of illustrating representative embodiments of the present disclosure, but the present disclosure is not limited to these embodiments.

In the present disclosure, “sheets” also include articles called “films”.

In the present disclosure, “(meth)acrylic” means acrylic or methacrylic.

In the present disclosure, “anisotropic thermal conductivity” means that the thermal conductivity differs depending on the direction. For example, scaly boron nitride exhibits anisotropic thermal conductivity in which the thermal conductivity in the major axis direction (crystal direction) is high and the thermal conductivity in the minor axis direction (thickness direction) is low. In the present disclosure, “isotropic thermal conductivity” means that thermal conductivity is isotropic rather than anisotropic in comparison to the anisotropic thermally conductive material. For example, spherical alumina particles exhibit isotropic thermal conductivity in which the thermal conductivity is substantially equal in every direction. Here, “substantially” means that the variation arising due to production error or the like is included, and it is intended that variation of approximately ±20% is permitted.

The thermally conductive sheet precursor according to an embodiment of the present disclosure includes isotropic thermally conductive aggregates in which anisotropic thermally conductive primary particles are aggregated, an anisotropic thermally conductive material not constituted by the aggregates, and a binder resin; wherein, upon the application of a pressure of from approximately 3 to approximately 12 MPa (also called “prescribed pressure” hereinafter) to the thermally conductive sheet precursor, at least some of the isotropic thermally conductive aggregates collapse.

The present disclosure will be described in further detail hereinafter with the objective of illustrating representative embodiments of the present invention, but the present invention is not limited to these embodiments.

### Thermally Conductive Sheet Precursor

### Isotropic Thermally Conductive Aggregates

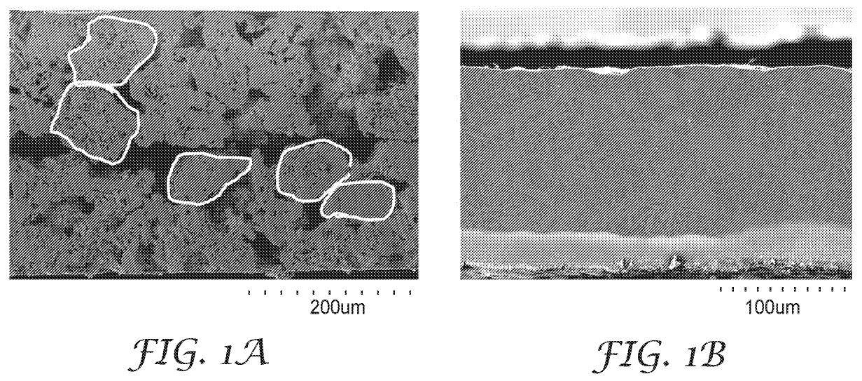

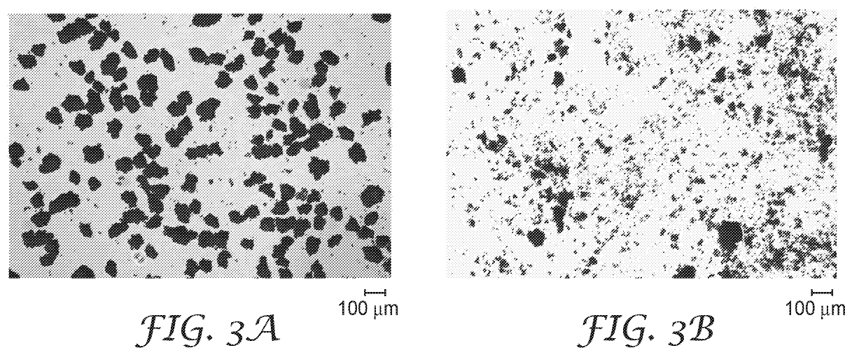

The isotropic thermally conductive aggregates contained in the thermally conductive sheet precursor of the present disclosure are secondary aggregated particles which are aggregated such that anisotropic thermally conductive primary particles exhibit isotropic thermal conductivity, such as those enclosed by the white lines in FIG. 1A. Any isotropic thermally conductive aggregates can be used as long as at least some of the aggregates collapse upon the application of a prescribed pressure to the thermally conductive sheet precursor. From the perspectives of thermal conductivity and dielectric breakdown resistance, the aggregates preferably have a collapse ratio of not less than approximately 20%, not less than approximately 30%, or not less than approximately 40% per 1 mm² after a prescribed pressure is applied, as illustrated in FIG. 3. Here, the collapse ratio refers to the ratio of change in the area average size obtained from a particle distribution analysis (Image J Software (Version 1.50i)) of an optical microscope image of aggregates recovered from the sheet.

### (Anisotropic Thermally Conductive Primary Particles)

The primary particles forming the isotropic thermally conductive aggregates may be any primary particles and are not limited to the following as long as the particles exhibit anisotropic thermal conductivity, but electrically insulating inorganic primary particles of aluminum nitride, silicon nitride, boron nitride, or the like having a needle shape, a flat shape, or a scaly shape may be used, for example, and these particles may be used alone or as a mixture of two or more types thereof. Of these, scaly hexagonal boron nitride (h-BN) is preferable from the perspectives of thermal conductivity, dielectric breakdown resistance, and the like after aggregates collapse.

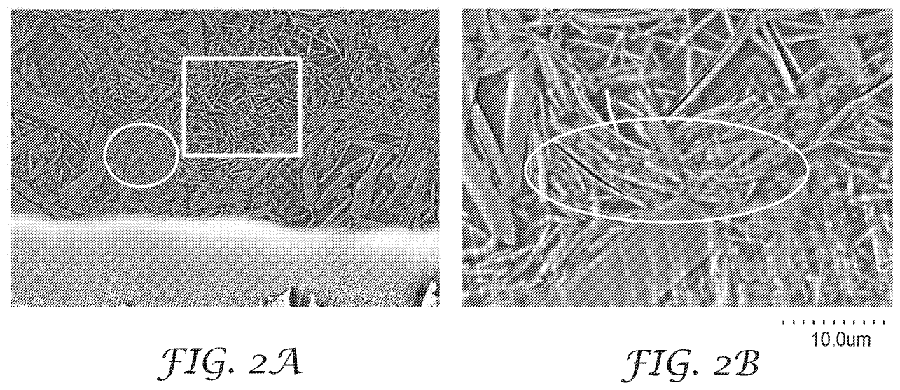

The size of the primary particles forming the isotropic thermally conductive aggregates may be adjusted appropriately such that the desired thermal conductivity and dielectric breakdown resistance of the thermally conductive sheet to be ultimately obtained can be achieved and is not limited to the following examples, but the size may be, for example, not less than approximately 1.5 times, not less than approximately 2 times, or not less than approximately 2.5 times the size (for example, average major axis length) of the primary or secondary particles of the anisotropic thermally conductive material described below. In a case where the isotropic thermally conductive aggregates and the anisotropic thermally conductive material are compounded with this configuration, as illustrated in the rectangular section of FIG. 2A, the primary particles of the collapsed aggregates tend to be oriented randomly, isotropic thermal conductivity can be easily imparted to the thermally conductive sheet, and the voids or the like present between aggregates are easy to be filled with the anisotropic thermally conductive material, as illustrated in the round portion of FIG. 2A, so the conductivity and dielectric breakdown resistance can be further enhanced.

### Porosity of Isotropic Thermally Conductive Aggregates

From the perspective of the collapse after the application of a prescribed pressure, the isotropic thermally conductive aggregates may have a porosity greater than approximately 50% or may have a porosity of not less than approximately 60% or not less than approximately 70%. This porosity can be controlled, for example, by adjusting the sintering temperature of the aggregates. In a case where the sintering temperature is high, the aggregates contract to increase its density, and then the strength of the aggregates increases, but the porosity decreases. On the other hand, in a case where the firing temperature is low, the contraction of the aggregates is reduced, and thus the porosity can be increased without increasing the strength of the aggregates. Here, in a case where the aggregates are fired at a high temperature, the aggregates tend to assume a spherical form, whereas in a case where they are fired at a low temperature, the aggregates tend to assume an imperfect spherical form—that is, a non-spherical form. The porosity of the aggregates can be calculated from the bulk density of the aggregates or can be determined by measuring the pore volume using a mercury intrusion porosimetry.

### Size of Isotropic Thermally Conductive Aggregates

The size of the isotropic thermally conductive aggregates may be regulated appropriately such that the desired thermal conductivity and dielectric breakdown resistance of the thermally conductive sheet to be ultimately obtained can be achieved and is not limited to the following examples, but the size may be, for example, not less than approximately 50 μm, not less than approximately 60 μm, or not less than approximately 70 μm. The upper limit of the average particle size is not particularly limited, but from the perspective of resistance to shedding from the thermally conductive sheet precursor, the upper limit may be, for example, not greater than approximately 300 μm, not greater than approximately 250 μm, or not greater than approximately 200 μm. Isotropic thermally conductive aggregates of this size may be easily randomized after collapse and easily express isotropic thermal conductivity in the thermally conductive sheet. Here, the average particle size of the isotropic thermally conductive aggregates may be determined, for example, using a laser diffraction/scattering method or an electron microscope such as a scanning electron microscope (SEM). It is particularly preferable to use the volume average size obtained from aggregate particle size distribution measurements using laser diffraction (wet measurement, LS13320, manufactured by Beckman Coulter).

### Compounding Ratio of Isotropic Thermally Conductive Aggregates

The compounding ratio of the isotropic thermally conductive aggregates may be adjusted appropriately such that the desired thermal conductivity and dielectric breakdown resistance of the thermally conductive sheet to be ultimately obtained can be achieved and is not limited to the following examples, but the compounding ratio may be, for example, within the range of not less than approximately 12.5 vol %, not less than approximately 14 vol %, or not less than approximately 15.5 vol % and not greater than approximately 57.5 vol %, not greater than approximately 52.5 vol %, or not greater than approximately 47.5 vol % per 100 vol % of the thermally conductive sheet. A thermally conductive sheet precursor containing isotropic thermally conductive aggregates at this compounding ratio can further enhance the conductivity and dielectric breakdown resistance of the thermally conductive sheet that is ultimately obtained. Here, voids are included in the aggregates or the like prior to collapse in the thermally conductive sheet precursor, but the true density of each material is used for the calculation of vol %, and these voids are not included in the vol % values described above.

Anisotropic Thermally Conductive Material

The anisotropic thermally conductive material included in the thermally conductive sheet precursor of the present disclosure refers to an anisotropic thermally conductive material not constituted by the isotropic thermally conductive aggregates described above—that is, an anisotropic thermally conductive material that is present separately from the anisotropic thermally conductive primary particles forming the isotropic thermally conductive aggregates. As illustrated by the circular portion in FIG. 2A, this anisotropic thermally conductive material is easily disposed between isotropic thermally conductive aggregates and exhibits excellent filling properties. Thus, the anisotropic thermally conductive material is thought to fulfill a function of enhancing the conductivity and dielectric breakdown resistance of the thermally conductive sheet that is ultimately obtained.

The anisotropic thermally conductive material of the present disclosure may be any material as long as the material exhibits the function described above and is not limited to the following examples, but at least one type selected from anisotropic thermally conductive and electrically insulating inorganic primary particles of aluminum nitride, silicon nitride, boron nitride, or the like having a needle shape, a flat shape, or a scaly shape and secondary particles aggregated such that these inorganic primary particles exhibit anisotropic thermal conductivity, for example, may be used. Of these, primary or secondary particles of scaly hexagonal boron nitride (h-BN) is preferable from the perspectives of thermal conductivity, dielectric breakdown resistance, and the like of the thermally conductive sheet that is ultimately obtained. Here, “secondary particles aggregated such that the inorganic primary particles exhibit anisotropic thermal conductivity” are the particles disclosed in US 2012/0114905, for example, and such secondary particles can be produced by applying inorganic primary particles of boron nitride or the like between rolls that rotate in two different directions to compact the primary particles.

### Size of Anisotropic Thermally Conductive Material

The size of the anisotropic thermally conductive material of the present disclosure may be regulated appropriately to exhibit the function described above and is not limited to the following examples, but the size may yield an average major axis length of not less than approximately 1 μm, not less than approximately 1.5 μm, or not less than approximately 2 μm and not greater than approximately 9 μm, not greater than approximately 8.5 μm, or not greater than approximately 8 μm. As illustrated in the circular portion of FIG. 2A, an anisotropic thermally conductive material of this size is easily disposed between isotropic thermally conductive aggregates and exhibits excellent filling properties. Thus, the anisotropic thermally conductive material can further enhance the conductivity and dielectric breakdown resistance of the thermally conductive sheet that is ultimately obtained. In particular, in the case of non-spherical, scaly inorganic primary or secondary particles or the like, the scaly anisotropic thermally conductive material is also simultaneously subjected to a pressure by the primary particles of the anisotropic thermally conductive material constituting the aggregates at the time of the collapse of the isotropic thermally conductive aggregates, for example, as illustrated in the elliptical portion of FIG. 2B. Thus, the pressurized portion increase its density such that the particles tend to be oriented in different directions rather than horizontally with respect to the thermally conductive sheet. As a result, the thermally conductive sheet is thought to more easily express isotropic thermal conductivity, which also enhances the dielectric breakdown resistance. Here, the average major axis length of the anisotropic thermally conductive material can be determined, for example, using an optical microscope or an electron microscope such as a scanning electron microscope. In this case, the average major axis length is preferably determined from at least 50 particles.

### Compounding Ratio of Anisotropic Thermally Conductive Material

The compounding ratio of the anisotropic thermally conductive material may be adjusted appropriately such that the desired thermal conductivity and dielectric breakdown resistance of the thermally conductive sheet to be ultimately obtained can be achieved and is not limited to the following examples, but the compounding ratio may be, for example, within the range of not less than approximately 2.5 vol %, not less than approximately 4.0 vol %, or not less than approximately 5.5 vol % and not greater than approximately 37.5 vol %, not greater than approximately 36.0 vol %, or not greater than approximately 34.5 vol % per 100 vol % of the thermally conductive sheet. A thermally conductive sheet precursor containing an anisotropic thermally conductive material at this compounding ratio can further enhance the conductivity and dielectric breakdown resistance of the thermally conductive sheet that is ultimately obtained. Here, voids are included in the aggregates or the like prior to collapse in the thermally conductive sheet precursor, but the true density of each material is used for the calculation of vol %, and these voids are not included in the vol % values described above.

### Binder Resin

The binder resin included in the thermally conductive sheet precursor of the present disclosure can be selected appropriately in accordance with the usage application or usage conditions such as the adhesiveness of the thermally conductive sheet that is ultimately obtained and is not limited to the following examples, but thermoplastic resins, thermosetting resins, or rubber-based resins such as silicone rubbers or fluorine rubbers may be used. For example, polyolefin resins such as polyethylene or polypropylene, polyester resins such as polyethylene terephthalate or polyethylene naphthalate, polycarbonate resins, polyamide resins, polyphenylene sulfide resins, or the like may be used as thermoplastic resins, and epoxy resins, (meth)acrylic resins, urethane resins, silicone resins, unsaturated polyester resins, phenol resins, melamine resins, polyimide resins, or the like may be used as thermosetting resins. These may be used alone or as a combination of two or more types thereof. Of these, epoxy resins are preferable from the perspective of the formability of the thermally conductive sheet. Examples of epoxy resins include bisphenol A epoxy resins, bisphenol F epoxy resins, ortho-cresol novolac epoxy resins, phenol novolac epoxy resins, alicyclic epoxy resins, and glycidyl-aminophenol epoxy resins, and these may be used alone or as a combination of two or more types thereof

### Compounding Ratio of Binder Resin

The compounding ratio of the binder resin may be adjusted appropriately such that the desired thermal conductivity and dielectric breakdown resistance of the thermally conductive sheet to be ultimately obtained can be achieved and is not limited to the following examples, but the compounding ratio may be, for example, within the range of not less than approximately 5 vol %, not less than approximately 11.5 vol %, or not less than approximately 18 vol % and not greater than approximately 85 vol %, not greater than approximately 82 vol %, or not greater than approximately 79 vol % per 100 vol % of the thermally conductive sheet precursor. A thermally conductive sheet precursor containing a binder resin at this compounding ratio can further enhance the performance such as the conductivity, dielectric breakdown resistance, and adhesiveness of the thermally conductive sheet that is ultimately obtained. Here, voids are included in the aggregates or the like prior to collapse in the thermally conductive sheet precursor, but the true density of each material is used for the calculation of vol %, and these voids are not included in the vol % values described above.

### Optionally Added Materials

The thermally conductive sheet precursor of the present disclosure may further contain additives such as flame retardants, pigments, dyes, fillers, reinforcing materials, leveling agents, coupling agents, defoaming agents, dispersants, thermal stabilizers, optical stabilizers, crosslinking agents, thermo-curing agents, light-curing agents, curing accelerators, tackifiers, plasticizers, reactive diluents, and solvents. The compounded amounts of these additives can be determined appropriately within a range that does not diminish the effect of the present invention.

### Thickness of Thermally Conductive Sheet Precursor

The thickness of the thermally conductive sheet precursor of the present disclosure can be selected appropriately in accordance with the usage application of the thermally conductive sheet that is ultimately obtained and is not limited to the following examples, but the thermally conductive sheet precursor may have a thickness greater than the maximum value of the length on the side where the isotropic thermally conductive aggregates are smallest. With this thickness, problems such as the shedding of isotropic thermally conductive aggregates can be reduced. Here, the length on the side where the isotropic thermally conductive aggregates are smallest may be determined as follows, for example. An image of the isotropic thermally conductive aggregates is obtained using an optical microscope and then, using the particle analysis function of Image J Software (Version 1.50i) on the image, the minor axis diameter obtained by elliptical approximation is determined as the length on the side where the isotropic thermally conductive aggregates are smallest. The maximum value of the length on the side where the isotropic thermally conductive aggregates are smallest may be defined as the maximum value among values obtained by measuring the length on the side where the aggregates are smallest for 100 aggregates.

### Thermally Conductive Sheet

### Thermally Conductive Sheet Characteristics

The thermally conductive sheet obtained from the thermally conductive sheet precursor of the present disclosure may have a thermal conductivity of not less than approximately 4 W/m·K, not less than approximately 4.5 W/m·K, or not less than approximately 5 W/m·K and a dielectric breakdown voltage of not less than approximately 5.0 kV, not less than approximately 5.5 kV, or not less than approximately 6.0 kV. A thermally conductive sheet having this thermal conductivity and dielectric breakdown voltage can be adequately used in a power module or the like of an electric vehicle (EV).

### Thickness of Thermally Conductive Sheet

The thickness of the thermally conductive sheet of the present disclosure can be selected appropriately in accordance with the usage application or the like and is not particularly limited to the following examples, but the thickness may be, for example, not less than approximately 80 μm, not less than approximately 100 μm, or not less than approximately 150 μm and not greater than approximately 400 μm, not greater than approximately 350 μm, or not greater than approximately 300 μm. The thermally conductive sheet of the present disclosure exhibits excellent dielectric breakdown resistance in addition to thermal conductivity, therefore, the thickness of the thermally conductive sheet can be made thin.

### Thermally Conductive Sheet Production Method

The production method for the thermally conductive sheet precursor of the present disclosure is not limited to the following. For example, a binder resin, a solvent, optional curing agents, or the like are compounded in a prescribed vessel and mixed while stirring for approximately 10 to approximately 60 seconds at approximately 1000 to approximately 3000 rpm using a high-speed mixer or the like to prepare a mixture A. Next, isotropic thermally conductive aggregates, an anisotropic thermally conductive material, and an optional solvent are further compounded with the mixture A and further mixed while stirring for approximately 10 to approximately 60 seconds at approximately 1000 to approximately 3000 rpm using a high-speed mixer or the like to prepare a mixture B. Next, a thermally conductive sheet precursor can be obtained by applying the mixture B to a release liner using a known coating method using a bar coater or a knife coater and then drying under prescribed conditions. This drying may be single-stage drying or drying of two or more stages. For example, drying may be performed for approximately 1 to approximately 10 minutes at approximately 50° C. to approximately 70° C., followed by drying for approximately 1 to approximately 10 minutes at approximately 80° C. to approximately 120° C. In a case where such multiple-stage drying is performed, a thermally conductive sheet precursor having voids such as that illustrated in FIG. 1A is easily obtained. Next, to the obtained thermally conductive sheet precursor, a pressure of at least approximately 3 MPa, at least approximately 4 MPa, or at least approximately 5 MPa is applied for approximately 1 to approximately 10 minutes at approximately 50° C. to approximately 70° C. and then a thermally conductive sheet such as that illustrated in FIG. 1B can be produced. Here, in a case where a thermo-curing agent is used, curing may be performed using the heat of the drying process described above or may be performed separately in another process such as the process of applying pressure or an additional heating process.

The thermally conductive sheet obtained by this method may separately contain, within the thermally conductive sheet, a portion in which the anisotropic thermally conductive material is not present and a plurality of collapsed primary particles from the isotropic thermally conductive aggregates are locally clustered, as illustrated in the square portion of FIG. 2A, and a portion in which the collapsed primary particles from the isotropic thermally conductive aggregates are not present and a plurality of anisotropic thermally conductive materials are locally clustered, as illustrated in the circular portion of FIG. 2A. In the case of a thermally conductive sheet obtained from a resin material prepared by simply mixing isotropic thermally conductive aggregates and an anisotropic thermally conductive material, the isotropic thermally conductive aggregates and the anisotropic thermally conductive material are typically dispersed and mixed uniformly, and thus local clustered portions such as those described above are not formed.

### Applications

The thermally conductive sheet of the present disclosure can be used as a heat-dissipating part, particularly for a power module, which is disposed to fill a gap between a heat-generating part such as an IC chip and a heat-dissipating part such as a heat sink or a heat pipe, for example, which are used in vehicles such as an electric vehicles (EV), household electric appliances, computer equipment, and the like, to enable the efficient transfer of heat generated from the heat-generating part to the heat-dissipating part.

### EXAMPLES

### Examples 1 to 9 and Comparative Examples 1 to 5

Specific embodiments of the present disclosure will be illustrated in the following examples, but the present disclosure is not limited to these examples.

The products and the like used in these examples are shown in Table 1 below.

TABLE 1

| Product name, | | |
|---|---|---|
| model number, | | |
| or abbreviation | Description | Source |
| jER (trade name) 152 | Phenol novolac liquid epoxy resin | Mitsui Chemical Co., Ltd. |
| | | (Chiyoda-ku, Tokyo, Japan) |
| YDCN-700-3 | Ortho-cresol novolac epoxy resin | Nippon Steel & Sumikin |
| | | Chemical Co., Ltd. |
| | | (Chiyoda-ku, Tokyo, Japan) |
| DICYANEX (trade name) | Curing agent: dicyandiamide | Evonik Japan |
| 1400F | | (Shinjuku-ku, Tokyo, Japan) |
| 3M (Trademark) Boron | Isotropic thermally conductive | 3M Japan |
| Nitride Cleaning Filler Type A | aggregates with an average particle | (Shinagawa-ku, Tokyo, Japan) |
| Agglomerate 100 (A100) | size of 84 μm in which scaly (plate- | |
| | like) boron nitride primary particles | |
| | are aggregated | |
| | Maximum value of length on | |
| | smallest side: 119 μm | |
| 3M (Trademark) Boron | Scaly (plate-like) boron nitride | 3M Japan |
| Nitride Cleaning Filler Type P | primary particles with an average | (Shinagawa-ku, Tokyo, Japan) |
| Platelet 003 (P003) | major axis length of 3 μm | |
| 3M (Trademark) Boron | Scaly (plate-like) boron nitride | 3M Japan |
| Nitride Cleaning Filler Type P | primary particles with an average | (Shinagawa-ku, Tokyo, Japan) |
| Platelet 007 (P007) | major axis length of 7 μm | |
| 3M (Trademark) Boron | Anisotropic thermally conductive | 3M Japan |
| Nitride Cleaning Filler Type F | secondary particles with an average | (Shinagawa-ku, Tokyo, Japan) |
| Flakes VSN1395 (VSN1395) | particle size of 7 μm in which scaly | |
| | (plate-like) boron nitride primary | |
| | particles are aggregated | |
| Advanced Alumina AA-18 | α-Alumina monocrystal particles | Sumitomo Chemical Co., Ltd. |
| | with a primary particle size of 18 μm | (Chuo-ku, Osaka, Japan) |
| Advanced Akunina AA-1.5 | α-Alumina monocrystal particles | Wako Pure Chemical |
| | with a primary particle size of 1.5 μm | Industries, Ltd. |
| | | (Chuo-ku, Osaka, Japan) |
| MEK | Methyl ethyl ketone | Mitsui Chemical Co., Ltd. |
| | | (Chiyoda-ku, Tokyo, Japan) |

The respective materials shown in Table 1 were mixed at the compounding ratios shown in Table 2 to produce the respective coating solutions for producing thermally conductive sheet precursors. Here, the numerical values in Table 2 all refer to parts by mass.

TABLE 2

| | Coating solution for thermally conductive sheet precursor | | | | | | | | | | | | |
|---|---|---|---|---|---|---|---|---|---|---|---|---|---|
| | T-0 | TA-1 | TA-2 | TA-3 | TA-4 | TA-5 | TA-6 | TA-7 | TA-8 | TB-1 | TB-2 | TB-3 | TB-4 |
| jER152 | 20 | 20 | 20 | 20 | 20 | 20 | 20 | 20 | 20 | 20 | 20 | 20 | 20 |
| YDCN-700-3 | 80 | 80 | 80 | 80 | 80 | 80 | 80 | 80 | 80 | 80 | 80 | 80 | 80 |
| DICYANEX | 8.1 | 8.1 | 8.1 | 8.1 | 8.1 | 8.1 | 8.1 | 8.1 | 8.1 | 8.1 | 8.1 | 8.1 | 8.1 |
| 1400F | | | | | | | | | | | | | |
| A100 | 225 | 214 | 203 | 191 | 180 | 135 | 90 | 45 | — | 191 | 180 | 158 | 135 |
| P003 | — | 11 | 23 | 34 | 45 | 90 | 135 | 180 | 225 | — | — | — | — |
| P007 | — | — | — | — | — | — | — | — | — | 34 | 45 | 67 | 90 |
| VSN1395 | — | — | — | — | — | — | — | — | — | — | — | — | — |
| AA-18 | — | — | — | — | — | — | — | — | — | — | — | — | — |
| AA-1.5 | — | — | — | — | — | — | — | — | — | — | — | — | — |
| MEK | 180 | 180 | 180 | 180 | 180 | 180 | 180 | 180 | 180 | 180 | 180 | 180 | 180 |
| Total amount | 513.1 | 513.1 | 513.1 | 513.1 | 513.1 | 513.1 | 513.1 | 513.1 | 513.1 | 513.1 | 513.1 | 513.1 | 513.1 |
| (parts) | | | | | | | | | | | | | |
| BN (vol %) | 50 | 50 | 50 | 50 | 50 | 50 | 50 | 50 | 50 | 50 | 50 | 50 | 50 |
| A100(%) | 100 | 95 | 90 | 85 | 80 | 60 | 40 | 20 | — | 85 | 80 | 70 | 60 |
| P003(%) | — | 5 | 10 | 15 | 20 | 40 | 60 | 80 | 100 | — | — | — | — |
| P007(%) | — | — | — | — | — | — | — | — | — | 15 | 20 | 30 | 40 |
| VSN1395(%) | — | — | — | — | — | — | — | — | — | — | — | — | — |
| AA-18(%) | — | — | — | — | — | — | — | — | — | — | — | — | — |
| AA-1.5(%) | — | — | — | — | — | — | — | — | — | — | — | — | — |
| Solid | 65 | 65 | 65 | 65 | 65 | 65 | 65 | 65 | 65 | 65 | 65 | 65 | 65 |
| content (%) | | | | | | | | | | | | | |

| | Coating solution for thermally conductive sheet precursor | | | | | | | | | | |
|---|---|---|---|---|---|---|---|---|---|---|---|
| | TB-5 | TB-6 | TB-7 | TC-1 | TC-2 | TC-3 | TC-4 | TC-A | TC-B | TD-1 | TE-1 |
| jER152 | 20 | 20 | 20 | 20 | 20 | 20 | 20 | 20 | 20 | 20 | 20 |
| YDCN-700-3 | 80 | 80 | 80 | 80 | 80 | 80 | 80 | 80 | 80 | 80 | 80 |
| DICYANEX | 8.1 | 8.1 | 8.1 | 8.1 | 8.1 | 8.1 | 8.1 | 8.1 | 8.1 | 8.1 | 8.1 |
| 1400F | | | | | | | | | | | |
| A100 | 112.5 | 56 | — | 169 | 112.5 | 56 | — | — | — | 191 | 191 |
| P003 | — | — | — | — | — | — | — | — | — | — | — |
| P007 | 112.5 | 169 | 225 | — | — | — | — | — | — | — | — |
| VSN1395 | — | — | — | 56 | 112.5 | 169 | 225 | 180 | 270 | — | — |
| AA-18 | — | — | — | — | — | — | — | — | — | 34 | — |
| AA-1.5 | — | — | — | — | — | — | — | — | — | — | 34 |
| MEK | 180 | 180 | 180 | 180 | 180 | 180 | 180 | 180 | 180 | 180 | 180 |
| Total amount | 513.1 | 513.1 | 513.1 | 513.1 | 513.1 | 513.1 | 513.1 | 513.1 | 513.1 | 513.1 | 513.1 |
| (parts) | | | | | | | | | | | |
| BN (vol %) | 50 | 50 | 50 | 50 | 50 | 50 | 50 | 40 | 60 | 50 | 50 |
| A100(%) | 50 | 25 | — | 75 | 50 | 25 | — | — | — | 85 | 85 |
| P003(%) | — | — | — | — | — | — | — | — | — | — | — |
| P007(%) | 50 | 75 | 100 | — | — | — | — | — | — | — | — |
| VSN1395(%) | — | — | — | 25 | 50 | 75 | 100 | 100 | 100 | — | — |
| AA-18(%) | — | — | — | — | — | — | — | — | — | 15 | — |
| AA-1.5(%) | — | — | — | — | — | — | — | — | — | — | 15 |
| Solid | 65 | 65 | 65 | 65 | 65 | 65 | 65 | 65 | 65 | 65 | 65 |
| content (%) | | | | | | | | | | | |

### Evaluation Tests

The characteristics and internal structures of the thermally conductive sheets were evaluated using the following methods.

### Thermal Conductivity Test

Thermal diffusivity is measured as follows using the flash analysis method of Hyperflash (trade name) LFA467 manufactured by the Netzsch Corporation. The thermally conductive sheet precursor is placed between two release liners, and this is placed inside a hot press machine (heat plate press machine N5042-00, available from NPa System Co., Ltd.). The precursor is cured by applying a prescribed pressure for 30 minutes at 180° C. to produce a sample A of a thermally conductive sheet having a thickness of approximately 200 μm. Next, the sample A is cut to a size of 10 mm×10 mm with a knife cutter to produce sample B, and this sample B is mounted in a sample holder. Prior to measurement, both sides of the sample B are coated with a thin layer of graphite (GRAPHIT33, Kontakt Chemie) to produce a sample C. In measurements, the temperature of the upper surface of the sample C is measured with an InSbIR detector after the bottom surface is irradiated with pulses of light (Xenon flash lamp, 230 V, duration of 20-30 μs). Measurements are taken three times for the sample C at 23° C. Next, the thermal diffusivity is calculated from the fit of the thermogram using the Cowan method. The thermal conductivity is calculated with Proteus (trade name) software available from the Netzsch Corporation based on the specific thermal capacity obtained by the thermal diffusivity, density, and DSC of the sample C.

### Dielectric Breakdown Voltage Test

A sample A is prepared with the same procedure as that described above. The dielectric breakdown voltage of the sample A is measured at a rate of 0.5 kV/s in the atmosphere using a puncture tester (TP-5120A) available from the Asao Electronics Corporation. Measurements are taken three times at different spots of the sample A, and the average value thereof is used as the dielectric breakdown voltage.

### Scanning Electron Microscope

A cross-sectional sample is produced using an IM4000 Plus ion milling device available from Hitachi High Technologies Co., Ltd., and the cross-sectional sample is covered with a 2 nm Pt/Pd layer using a sputtering machine. Next, the cross section of the sample is observed using an 53400N available from Hitachi High Technologies Co., Ltd.

Test 1: Relationship Between Relative Thickness and Dielectric Breakdown Voltage of Thermally Conductive Sheet after Application of Pressure

### Example 1

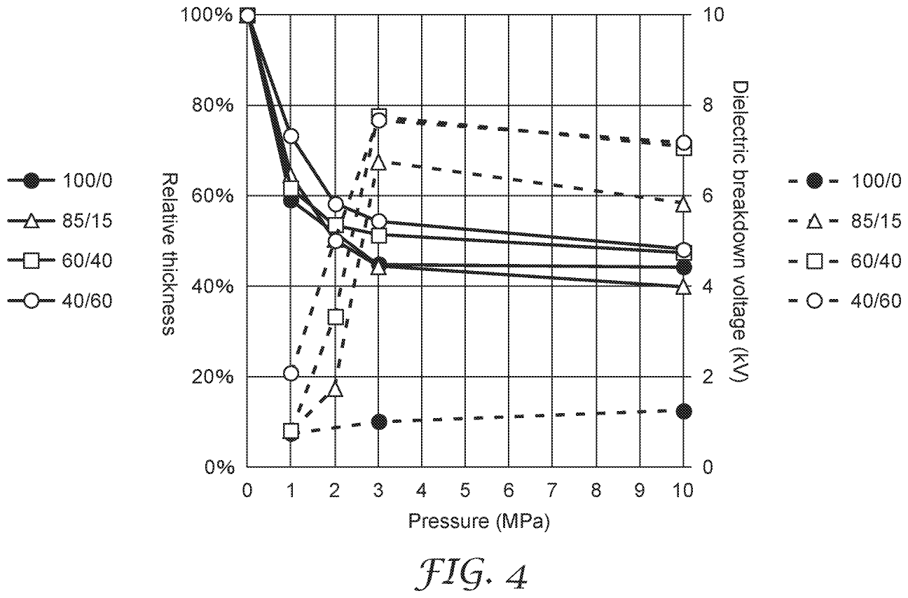

Immediately after a coating solution TA-3 for a thermally conductive sheet precursor containing A100 and P003 at a ratio of 85/15 was prepared, a release PET liner having a thickness of 38 μm (A31: available from Du Pont-Toray Co., Ltd.) was coated with a knife coater having a gap interval of 290 μm and dried for 5 minutes at 65° C. The sample was further dried for 5 minutes at 100° C. to produce each thermally conductive sheet precursor having a thickness of approximately 180 μm for applying various levels of pressure. Next, for each thermally conductive sheet precursor, two sheet precursors were laminated and pressures of 1 MPa, 2 MPa, 3 MPa, and 10 MPa were each applied for 5 minutes at 65° C. to produce a thermally conductive sheet. The results regarding the relative thickness of the obtained thermally conductive sheet, that is, the ratio of the thickness of the thermally conductive sheet to the thickness of the thermally conductive precursor, and the dielectric breakdown voltage are shown in FIG. 4. Here, embodiments in which a pressure of 1 MPa or 2 MPa was applied are used as reference examples.

### Example 2

A thermally conductive sheet was produced in the same manner as in Example 1 with the exception that a coating solution TA-5 for a thermally conductive sheet precursor containing A100 and P003 at a ratio of 60/40 was used instead of TA-3. The results regarding the relative thickness and dielectric breakdown voltage of the thermally conductive sheet are shown in FIG. 4. Here, embodiments in which a pressure of 1 MPa or 2 MPa was applied are also used as reference examples.

### Example 3

A thermally conductive sheet was produced in the same manner as in Example 1 with the exception that a coating solution TA-6 for a thermally conductive sheet precursor containing A100 and P003 at a ratio of 40/60 was used instead of TA-3. The results regarding the relative thickness and dielectric breakdown voltage of the thermally conductive sheet are shown in FIG. 4. Here, embodiments in which a pressure of 1 MPa or 2 MPa was applied are also used as reference examples.

### Comparative Example 1

A thermally conductive sheet was produced in the same manner as in Example 1 with the exception that a coating solution T-0 for a thermally conductive sheet precursor containing A100 and P003 at a ratio of 100/0 was used instead of TA-3. The results regarding the relative thickness and dielectric breakdown voltage of the thermally conductive sheet are shown in FIG. 4.

### Results

As can be seen from FIG. 4, in the thermally conductive sheet of Comparative Example 1, the relative thickness is reduced. That is, the thickness of the thermally conductive sheet is reduced in comparison to the thickness of the precursor. Therefore, although the isotropic thermally conductive aggregates (A100) may have been collapsed within the sheet, there was very little change in the value of the dielectric breakdown voltage. On the other hand, in the modes of Examples 1 to 3 corresponding to the thermally conductive sheet of the present disclosure, it was confirmed that the value of the dielectric breakdown voltage increases dramatically as the applied pressure increases from 1 MPa to 3 MPa. As a result, it was determined that the combined use of isotropic thermally conductive aggregates and an anisotropic thermally conductive material greatly contributes to dielectric breakdown resistance.

### Test 2: Relationship Between Compounding Ratio of Various Anisotropic Thermally Conductive Materials and Dielectric Breakdown Voltage

### Example 4

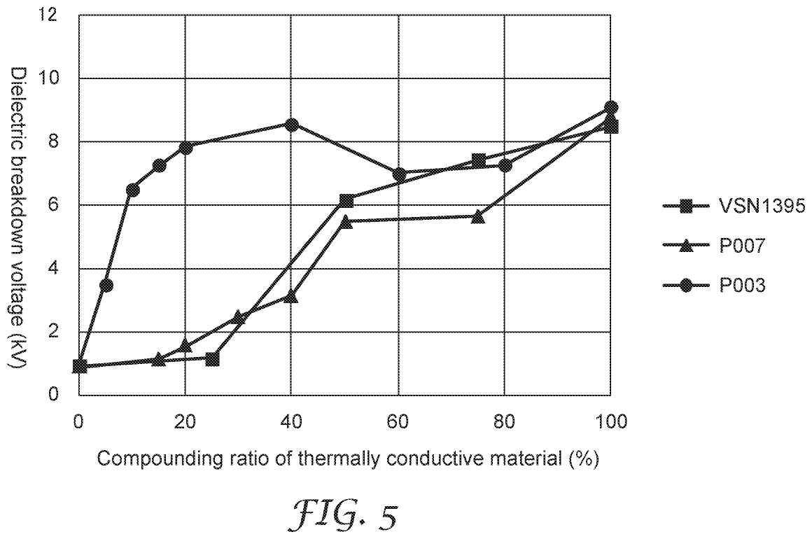

A thermally conductive sheet was produced in the same manner as in Example 1 with the exception that T-0 containing no anisotropic thermally conductive material and TA-1 to TA-8 containing P003 as an anisotropic thermally conductive material were used as a coating solution for a thermally conductive sheet precursor, and that the applied pressure was fixed at 3 MPa. The results related to the compounding ratio of the anisotropic thermally conductive material and the dielectric breakdown voltage of the obtained thermally conductive sheet are shown in FIG. 5. Here, embodiments in which the compounding ratio of the anisotropic thermally conductive material is 0% or 100% are used as reference examples.

### Example 5

A thermally conductive sheet was produced in the same manner as in Example 1 with the exception that T-0 containing no anisotropic thermally conductive material and TB-1 to TB-7 containing P007 as an anisotropic thermally conductive material were used as a coating solution for a thermally conductive sheet precursor, and that the applied pressure was fixed at 3 MPa. The results related to the compounding ratio of the anisotropic thermally conductive material and the dielectric breakdown voltage in the obtained thermally conductive sheet are shown in FIG. 5. Here, embodiments in which the compounding ratio of the anisotropic thermally conductive material is 0% or 100% are used as reference examples.

### Example 6

A thermally conductive sheet was produced in the same manner as in Example 1 with the exception that T-0 containing no anisotropic thermally conductive material and TC-1 to TC-4 containing VSN1395 as an anisotropic thermally conductive material were used as a coating solution for a thermally conductive sheet precursor, and that the applied pressure was fixed at 3 MPa. The results related to the compounding ratio of the anisotropic thermally conductive material and the dielectric breakdown voltage of the obtained thermally conductive sheet are shown in FIG. 5. Here, embodiments in which the compounding ratio of the anisotropic thermally conductive material is 0% or 100% are used as reference examples.

### Results

As can be seen from FIG. 5, in each of the thermally conductive sheets of Examples 4 to 6, it was confirmed that the value of the dielectric breakdown voltage also tends to increase as the compounded amount of the anisotropic thermally conductive material increases. In particular, in the case of the thermally conductive sheet of Example 4 using P003 as an anisotropic thermally conductive material, it was confirmed that a dielectric breakdown voltage of over approximately 4 kV can be achieved even when the compounded amount thereof is low.

### Test 3: Relationship Between Compounding Ratio of Anisotropic Thermally Conductive Material (P003) and Dielectric Breakdown Voltage and Thermal Conductivity

### Example 7

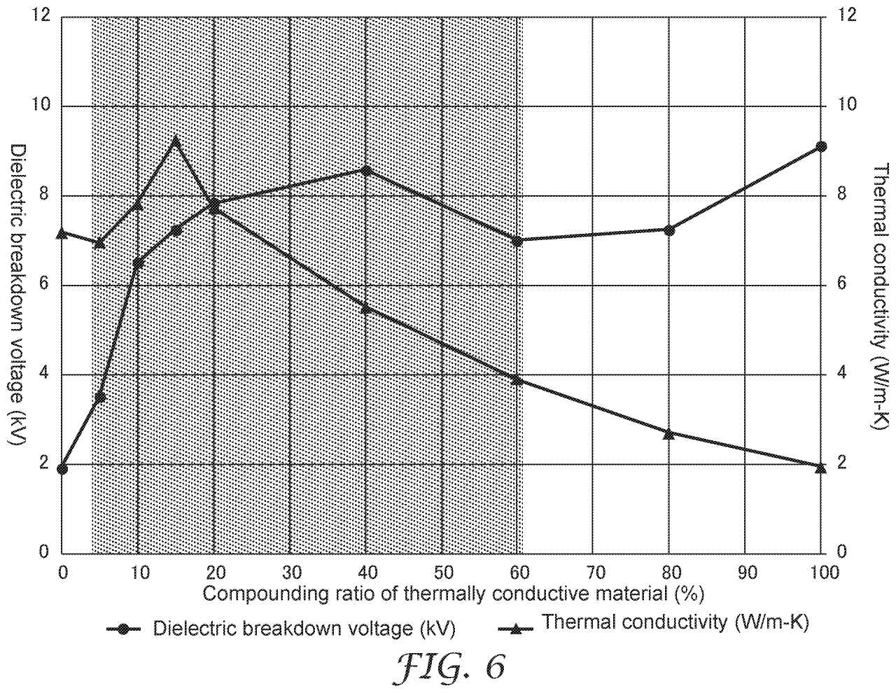

A thermally conductive sheet was produced in the same manner as in Example 1 with the exception that T-0 containing no anisotropic thermally conductive material and TA-1 to TA-8 containing P003 as an anisotropic thermally conductive material were used as a coating solution for a thermally conductive sheet precursor, and that the applied pressure was fixed at 3 MPa. The results related to the compounding ratio of the anisotropic thermally conductive material in the obtained thermally conductive sheet and the dielectric breakdown voltage and thermal conductivity are shown in FIG. 6. Here, embodiments in which the compounding ratio of the anisotropic thermally conductive material is 0% or 100% are used as reference examples.

### Results

As can be seen from FIG. 6, it was determined that increases in the compounded amount of the anisotropic thermally conductive material greatly contribute to the enhancement of the dielectric breakdown voltage and that this may be a factor that reduces the value of the thermal conductivity. A reason for the decrease in the thermal conductivity may be that the ratio of isotropic thermally conductive aggregates decreases as the ratio of the anisotropic thermally conductive material increases, and the proportion of random orientation of anisotropic thermally conductive primary particles after aggregate collapse also decreases. Although not limited to the following, because the results also may vary due to the required performance or the like of the thermally conductive sheet, the regions of the dot areas may be considered preferable regions in the embodiments illustrated in FIG. 6.

### Test 4: Relationship Between Compounding Ratio of Anisotropic Thermally Conductive Material and the Dielectric Breakdown Voltage and Thermal Conductivity in Thermally Conductive Sheet Containing Only Anisotropic Thermally Conductive Material (VSN1395)

### Comparative Example 2

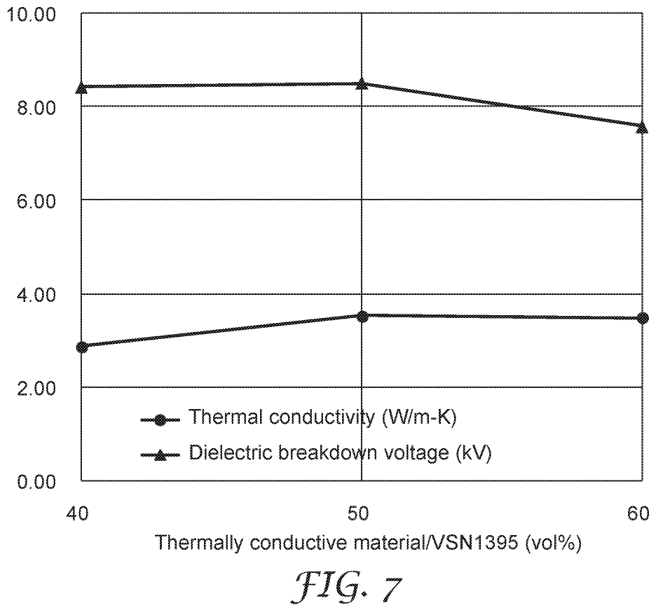

A thermally conductive sheet was produced in the same manner as in Example 1 with the exception that TC-4, TC-A, and TC-B containing no isotropic thermally conductive aggregates and containing VSN1395 as an anisotropic thermally conductive material were used as a coating solution for a thermally conductive sheet precursor, and that the applied pressure was fixed at 3 MPa. The results related to the compounding ratio of the anisotropic thermally conductive material in the obtained thermally conductive sheet and the dielectric breakdown voltage and thermal conductivity are shown in FIG. 7.

### Results

As can be seen from FIG. 7, it was confirmed that even in a case where the compounding ratio of the anisotropic thermally conductive material is increased with respect to the thermally conductive sheet, it is difficult to simultaneously enhance the performance with regard to both the dielectric breakdown resistance and the thermal conductivity in a configuration containing only an anisotropic thermally conductive material.

### Test 5: Relationship Between Compounding Ratio of Anisotropic Thermally Conductive Material (VSN1395) and Dielectric Breakdown Voltage

### Example 8

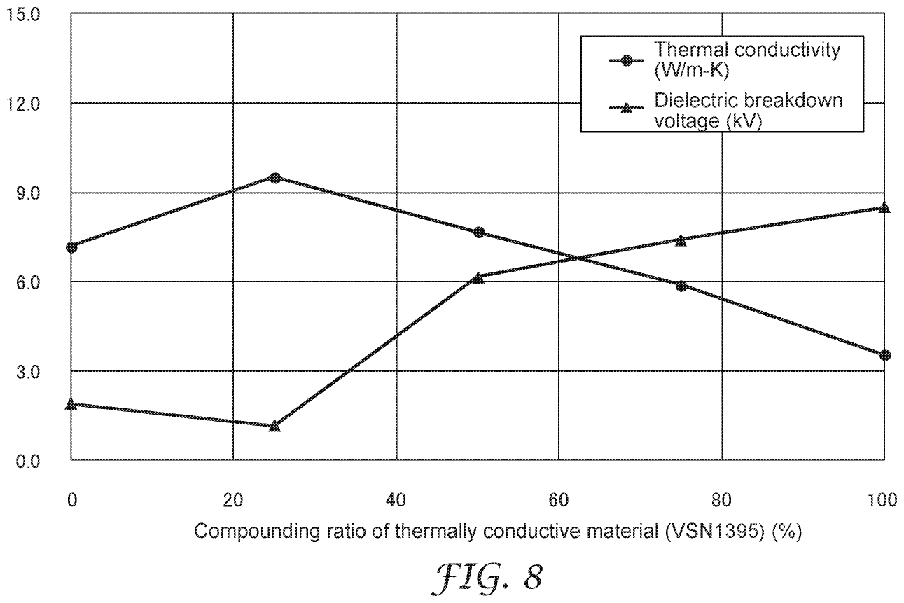

A thermally conductive sheet was produced in the same manner as in Example 1 with the exception that T-0 containing no anisotropic thermally conductive material and TC-1 to TC-4 containing VSN1395 as an anisotropic thermally conductive material were used as a coating solution for a thermally conductive sheet precursor, and that the applied pressure was fixed at 3 MPa. The results related to the compounding ratio of the anisotropic thermally conductive material in the obtained thermally conductive sheet and the dielectric breakdown voltage and thermal conductivity are shown in FIG. 8. Here, embodiments in which the compounding ratio of the anisotropic thermally conductive material is 0% or 100% are used as reference examples.

### Results

As can be seen from FIG. 8, it was confirmed that, different from the results of Test 4, even in a case where the anisotropic thermally conductive material is VSN1395, the performance with regard to both the dielectric breakdown resistance and the thermal conductivity can be enhanced in the same manner as in the results of Test 3 (wherein the anisotropic thermally conductive material is a P003-based material) by using isotropic thermally conductive aggregates in combination.

Test 6: Relationship Between Thickness and Dielectric Breakdown Voltage in Thermally Conductive Sheet of One-Component System Containing Only Isotropic Thermally Conductive Aggregates and Mixture-Component System Containing Mixture of Isotropic Thermally Conductive Aggregates and Anisotropic Thermally Conductive Material

### Example 9

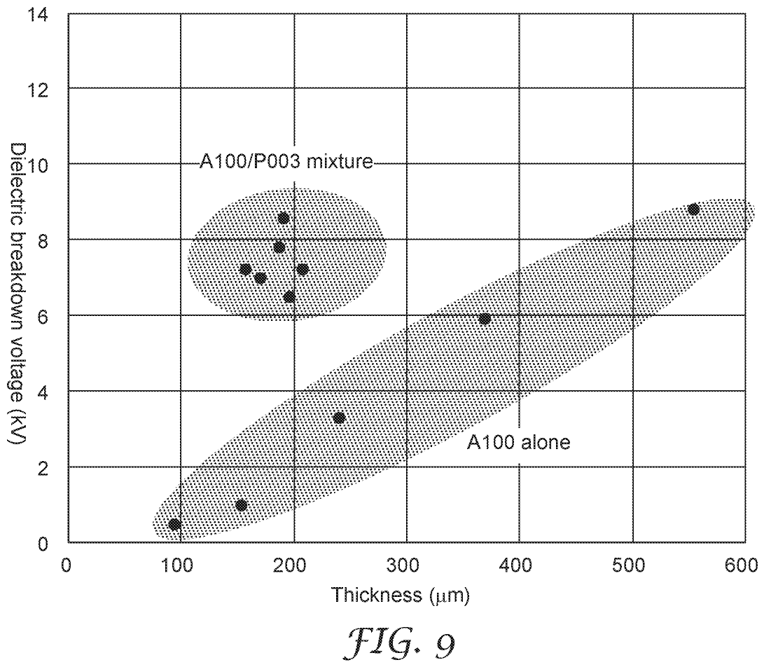

A thermally conductive sheet was produced in the same manner as in Example 1 with the exception that TA-2 to TA-7 containing P003 as an anisotropic thermally conductive material were used as a coating solution for a thermally conductive sheet precursor, that the applied pressure was fixed at 3 MPa, and that the thickness of the thermally conductive sheet was set to 196 μm (TA-2 system), 207 μm (TA-3 system), 187 μm (TA-4 system), 190 μm (TA-5 system), 169 μm (TA-6 system), and 157 μm (TA-7 system). The results related to the thickness and the dielectric breakdown voltage of the obtained thermally conductive sheet are shown in FIG. 9.

### Comparative Example 3

A thermally conductive sheet was produced in the same manner as in Example 1 with the exception that TA-0 containing only isotropic thermally conductive aggregates was used as a coating solution for a thermally conductive sheet precursor, that the applied pressure was fixed at 3 MPa, and that the thickness of the thermally conductive sheet was set to 94 μm, 153 μm, 239 μm, 369 μm, and 553 μm. The results related to the thickness and the dielectric breakdown voltage of the obtained thermally conductive sheet are shown in FIG. 9.

### Results

As can be seen from FIG. 9, it was confirmed that the configuration of Example 9, which corresponds to an embodiment of the thermally conductive sheet of the present disclosure, exhibits higher dielectric breakdown resistance than the configuration of Comparative Example 3, even if the thickness of the thermally conductive sheet is small.

### Test 7: Relationship Between Dielectric Breakdown Voltage and Thermal Conductivity in Thermally Conductive Sheet Containing Isotropic Thermally Conductive Aggregates and Alumina Powder

### Comparative Example 4

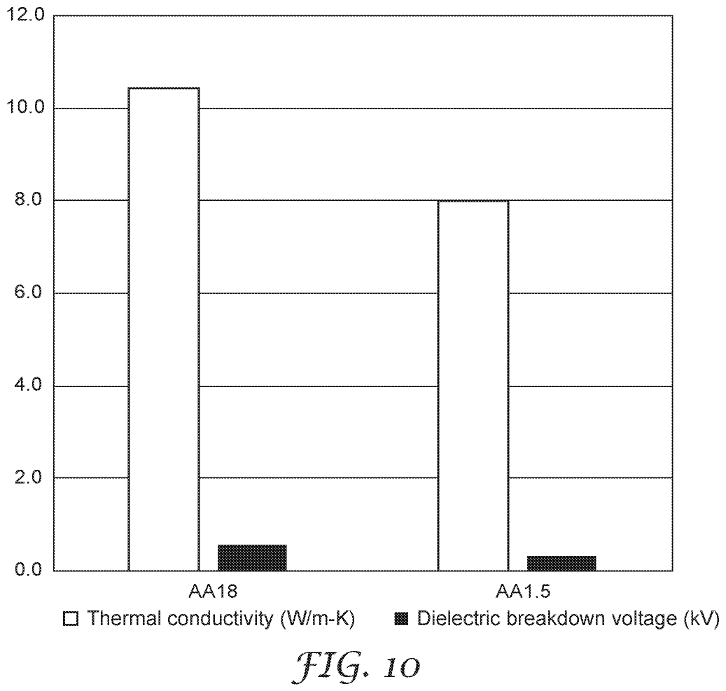

A thermally conductive sheet was produced in the same manner as in Example 1 with the exception that TD-1 using an isotropic thermally conductive material AA18 was used as a thermally conductive material and that the applied pressure was fixed at 3 MPa. The results related to the thermal conductivity and dielectric breakdown voltage of the obtained thermally conductive sheet are shown in FIG. 10.

### Comparative Example 5

A thermally conductive sheet was produced in the same manner as in Example 1 with the exception that TE-1 using an isotropic thermally conductive material AA1.5 was used as a thermally conductive material and that the applied pressure was fixed at 3 MPa. The results related to the thermal conductivity and dielectric breakdown voltage of the obtained thermally conductive sheet are shown in FIG. 10.

### Results

As can be seen from FIG. 10, it was confirmed that when spherical alumina, which is an isotropic thermally conductive material, is used as a thermally conductive material, the performance with regard to both the thermal conductivity and the dielectric breakdown resistance of the thermally conductive sheet cannot be enhanced.

It will be obvious to those skilled in the art that the embodiments and examples described above can be variously modified without departing from the basic principles of the present invention. In addition, it will be obvious to those skilled in the art that various improvements and modifications of the present invention can be made without departing from the gist and scope of the present invention.

1. A thermally conductive sheet precursor comprising isotropic thermally conductive aggregates in which anisotropic thermally conductive primary particles are aggregated, an anisotropic thermally conductive material not constituted by the aggregates, and a binder resin; wherein upon the application of a pressure from 3 to 12 MPa to the thermally conductive sheet precursor, at least some of the isotropic thermally conductive aggregates collapse, wherein the isotropic thermally conductive aggregates have a porosity of greater than 50%.

2. (canceled)

3. The thermally conductive sheet precursor according to claim 1, wherein the thermally conductive sheet precursor includes from 12.5 to 57.5 vol % of the isotropic thermally conductive aggregates and from 2.5 to 37.5 vol % of the anisotropic thermally conductive material.

4. The thermally conductive sheet precursor according to claim 1, wherein an average particle size of the isotropic thermally conductive aggregates is not less than 50 μm, and an average major axis length of the anisotropic thermally conductive material is from 1 to 9 μm.

5. The thermally conductive sheet precursor according to claim 1, wherein the anisotropic thermally conductive material is at least one type selected from anisotropic thermally conductive primary particles and secondary particles aggregated such that anisotropic thermally conductive primary particles exhibit anisotropic thermal conductivity.

6. The thermally conductive sheet precursor according to claim 5, wherein the primary particles of the isotropic thermally conductive aggregates are at least 1.5 times greater than the anisotropic thermally conductive primary particles or secondary particles.

7. The thermally conductive sheet precursor according to claim 1, wherein the isotropic thermally conductive aggregates and the anisotropic thermally conductive material include primary particles of boron nitride.

8. A thermally conductive sheet formed from the thermally conductive sheet precursor described in claim 1, wherein the thermally conductive sheet has a thermal conductivity of not less than 4 W/m·K and a dielectric breakdown voltage of not less than 5.0 kV.

9. The thermally conductive sheet according to claim 8 comprising a portion in which a plurality of collapsed primary particles from the isotropic thermally conductive aggregates are locally aggregated and a portion in which a plurality of the anisotropic thermally conductive materials are locally aggregated.

10. A production method for a thermally conductive sheet comprising:
preparing a mixture containing isotropic thermally conductive aggregates in which anisotropic thermally conductive primary particles are aggregated, an anisotropic thermally conductive material not constituted by the aggregates, and a binder resin;
forming a thermally conductive sheet precursor using the mixture; and
forming a thermally conductive sheet by applying a pressure of at least 3 MPa to the thermally conductive sheet precursor.
